(19) United States
(12) Patent Application Publication
(10) Pub. No.: US 2024/0297026 A1
(43) Pub. Date: Sep. 5, 2024

(54) SUBSTRATE FIXING DEVICE

(71) Applicant: SHINKO ELECTRIC INDUSTRIES CO., LTD., Nagano-shi (JP)

(72) Inventors: Masahiro Sunohara, Nagano (JP); Riku Nishikawa, Nagano (JP); Shun Takagi, Nagano (JP); Sakura Ando, Nagano (JP)

(21) Appl. No.: 18/590,384

(22) Filed: Feb. 28, 2024

(30) Foreign Application Priority Data
Mar. 1, 2023 (JP) 2023-031323

(51) Int. Cl. H01J 37/32; H01L 21/683

(52) U.S. Cl. CPC H01J 37/32724; H01L 21/6833; H01J 2237/334

(57) ABSTRACT

A substrate fixing device includes a base plate, a heating portion provided on the base plate, a metal layer provided on the heating portion, and an electrostatic chuck provided on the metal layer. In the substrate fixing device, the metal layer is made of the same material as the base plate.

### CROSS-REFERENCE TO RELATED APPLICATIONS

This application claims priority from Japanese Patent Application No. 2023-031323, filed on Mar. 1, 2023, the entire content of which is incorporated herein by reference.

### TECHNICAL FIELD

The present invention relates to a substrate fixing device.

### BACKGROUND ART

In the related art, a film forming apparatus (for example, a CVD apparatus or a PVD apparatus) or a plasma etching apparatus used in manufacturing a semiconductor device such as an IC or an LSI includes a stage for accurately holding a wafer in a vacuum processing chamber.

As such a stage, for example, a substrate fixing device has been proposed that suctions and holds a wafer as an object to be suctioned by an electrostatic chuck mounted on a base plate.

Examples of the substrate fixing device include a substrate fixing device having a structure provided with a heating element for adjusting the temperature of the wafer. In the substrate fixing device, the heating element is provided in, for example, an insulating layer provided adjacent to the electrostatic chuck. In order to equalize the heat generated by the heating element, a metal layer made of copper or the like may be provided closer to the electrostatic chuck than to the heating element.

### SUMMARY OF INVENTION

In the substrate fixing device having the structure described above, warpage may be a problem.

The present invention has been made in view of the points described above, and an object of the present invention is to provide a substrate fixing device that can reduce warpage.

According to one aspect of the present disclosure, there is provided a substrate fixing device includes a base plate, a heating portion provided on the base plate, a metal layer provided on the heating portion, and an electrostatic chuck provided on the metal layer. In the substrate fixing device, the metal layer is made of the same material as the base plate.

According to one aspect of the present disclosure, it is possible to provide a substrate fixing device that can reduce warpage.

### BRIEF DESCRIPTION OF DRAWINGS

FIGS. 1A and 1B are cross-sectional views showing a simplified example of a substrate fixing device according to a first embodiment;

FIGS. 2A to 2C are views (part 1) showing a manufacturing process of the substrate fixing device according to the first embodiment;

FIGS. 3A to 3C are views (part 2) showing the manufacturing process of the substrate fixing device according to the first embodiment;

FIGS. 4A and 4B are views (part 3) showing the manufacturing process of the substrate fixing device according to the first embodiment; and

FIG. 5 is a view showing a simulation result of temperature uniformity.

### DESCRIPTION OF EMBODIMENTS

Hereinafter, an embodiment of the invention will be described with reference to the drawings. In the drawings, the same components are denoted by the same reference signs, and the overlapping description may be omitted.

### First Embodiment

### [Structure of Substrate Fixing Device]

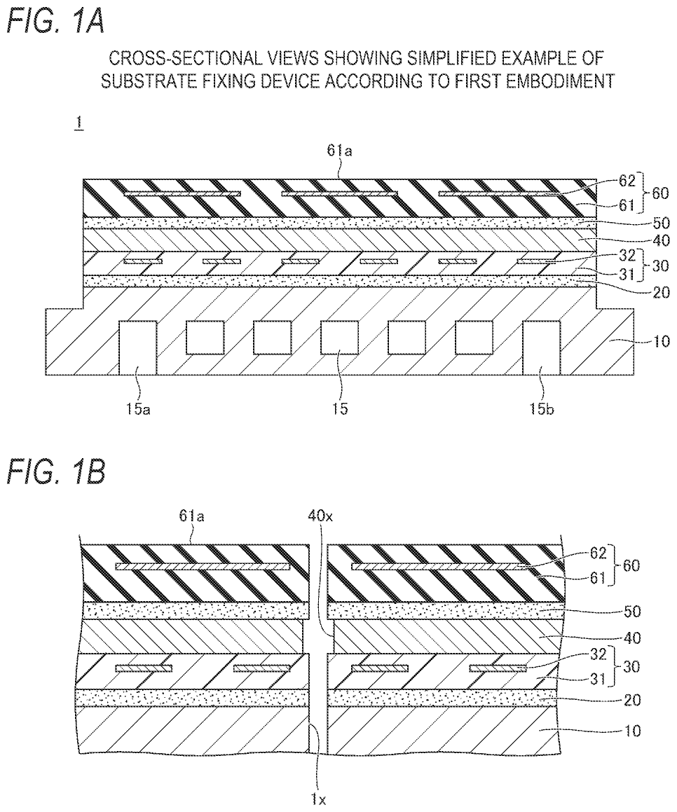

FIGS. 1A and 1B are cross-sectional views showing a simplified example of a substrate fixing device according to a first embodiment. FIG. 1A is an overall cross-sectional view, and FIG. 1B is a partial cross-sectional view. With reference to FIG. 1, a substrate fixing device 1 includes, as main components, a base plate 10, an adhesive layer 20, a heating portion 30, a metal layer 40, an adhesive layer 50, and an electrostatic chuck 60.

The base plate 10 is a member on which the heating portion 30 and the electrostatic chuck 60 are mounted. The thickness of the base plate 10 can be, for example, approximately 20 mm or more and 50 mm or less. The base plate 10 can be made of, for example, metal such as aluminum, copper, or titanium. Among these, it is preferable to use aluminum, which is inexpensive and easy to process.

The base plate 10 can also be used as an electrode or the like for controlling plasma. By supplying a predetermined high frequency power to the base plate 10, it is possible to control the energy for causing generated ions or the like in the plasma state to collide with the wafer suctioned on the electrostatic chuck 60, and to effectively perform the etching processing.

A water channel 15 may be formed inside the base plate 10. The water channel 15 includes a cooling water introducing portion 15a at one end and a cooling water discharging portion 15b at the other end. The water channel 15 is connected to a cooling water control device (not shown) provided outside the substrate fixing device 1. The cooling water control device (not shown) introduces the cooling water from the cooling water introducing portion 15a into the water channel 15, and discharges the cooling water from the cooling water discharging portion 15b. By circulating the cooling water through the water channel 15 and cooling the base plate 10, the wafer suctioned on the electrostatic chuck 60 can be cooled. In addition to the water channel 15, the base plate 10 may be provided with a gas channel or the like for introducing an inert gas to cool the wafer suctioned on the electrostatic chuck 60.

The heating portion 30 is provided on the base plate 10. The heating portion 30 is fixed to the base plate 10 via, for example, the adhesive layer 20. As the adhesive layer 20, for example, a silicone adhesive can be used. The thickness of the adhesive layer 20 can be, for example, approximately 2 mm. The thermal conductivity of the adhesive layer 20 is preferably 2 W/mK or more. The adhesive layer 20 may have a laminated structure in which a plurality of adhesive layers are laminated. For example, by forming the adhesive layer 20 into a two-layer structure combining an adhesive with high thermal conductivity and an adhesive with low elastic modulus, it is possible to attain an effect of reducing the stress caused by the difference in thermal expansion with the metal base plate.

The heating portion 30 includes an insulating layer 31 and a heating element 32 provided in the insulating layer 31. The periphery of the heating element 32 is covered with the insulating layer 31 and is protected from the outside.

As the insulating layer 31, for example, epoxy resin or bismaleimide triazine resin having high thermal conductivity and high heat resistance can be used. The thermal conductivity of the insulating layer 31 is preferably 3 W/mK or more. By containing a filler such as alumina or aluminum nitride in the insulating layer 31, the thermal conductivity of the insulating layer 31 can be improved. The glass transition temperature (Tg) of the insulating layer 31 is preferably 250° C. or higher. The thickness of the insulating layer 31 is preferably approximately 100 μm to 150 μm, and the thickness variation of the insulating layer 31 is preferably ±10% or less.

The heating element 32 generates heat by applying a voltage from outside the substrate fixing device 1, and heats a placement surface 61a of a base 61 to be described later to a predetermined temperature. For example, the heating element 32 can heat the placement surface 61a of the base 61 to approximately 250° C. to 300° C. As the material of the heating element 32, for example, copper (Cu), tungsten (W), nickel (Ni), aluminum (Al), constantan (an alloy of Cu/Ni/Mn/Fe), geranin (an alloy of Cu/Mn/Sn), and manganin (an alloy of Cu/Mn/Ni) can be used. The heating element 32 can have, for example, a concentric circular pattern.

In order to improve the adhesion between the heating element 32 and the insulating layer 31 at a high temperature, it is preferable that at least one surface (one or both of the upper and lower surfaces) of the heating element 32 is roughened. Of course, both the upper and lower surfaces of the heating element 32 may be roughened. In this case, different roughening methods may be used for the upper surface and the lower surface of the heating element 32. The roughening method is not particularly limited, and examples thereof include a method using etching, a method using a coupling agent-based surface modification technique, and a method using dot processing using a UV-YAG laser having a wavelength of 355 nm or less.

The metal layer 40 is provided on the heating portion 30. The metal layer 40 is made of the same material as the base plate 10. The metal layer 40 can be formed of metal such as aluminum, copper, or titanium. The metal layer 40 is made of the same material as the base plate 10, so that warpage of the substrate fixing device 1 can be reduced. The thickness of the metal layer 40 is smaller than the thickness of the base plate 10. However, from the viewpoint of reducing warpage, the thickness of the metal layer 40 is preferably 1/200 or more of the thickness of the base plate 10.

The metal layer 40 is a layer that uniformly diffuses the heat generated by the heating element 32 (alleviates uneven heat generation). The metal layer 40 is preferably provided directly on the entire surface of the insulating layer 31 on the electrostatic chuck 60 side. Accordingly, it is possible to improve the temperature uniformity on the placement surface 61a of the electrostatic chuck 60 even when uneven heat generation occurs due to the variation in the thickness direction of the heating element 32 or the like. The side surface of the metal layer 40 may be exposed to the outside of the substrate fixing device 1.

The thickness of the metal layer 40 is preferably 5 times or more the thickness of the heating element 32. Accordingly, the temperature uniformity on the placement surface 61a of the electrostatic chuck 60 can be further improved. The thickness of the metal layer 40 is more preferably 10 times or more the thickness of the heating element 32. Accordingly, the temperature uniformity on the placement surface 61a of the electrostatic chuck 60 can be further improved.

The thickness of the metal layer 40 may be, for example, 100 μm or more. The thickness of the metal layer 40 is preferably 200 μm or more. The thickness of the metal layer 40 is more preferably 500 μm or more. As the metal layer 40 is thicker, the temperature uniformity on the placement surface 61a of the electrostatic chuck 60 can be improved. On the other hand, if the metal layer 40 is too thick, the entire substrate fixing device 1 becomes too thick. Therefore, the thickness of the metal layer 40 is preferably 1000 μm or less. Since it is difficult to form the heating element 32 thickly from the viewpoint of wiring formability, it is preferable that the heating element 32 has a thickness of 100 μm or less. The thickness of the heating element 32 may be, for example, 10 μm or more and 100 μm or less.

As shown in FIG. 1B, the substrate fixing device 1 may be formed with a through hole 1x penetrating from the base plate 10 to the electrostatic chuck 60. The through hole 1x is, for example, a lift pin hole or a gas hole. In this case, the metal layer 40 has an opening 40x at a position corresponding to the through hole 1x. The through hole 1x and the opening 40x are, for example, circular when viewed from the placement surface 61a side. In this case, the opening diameter of the opening 40x may be larger than the hole diameter of the through hole 1x, and is preferably the same as the hole diameter of the through hole 1x. Accordingly, the contact area between the upper surface of the insulating layer 31 and the lower surface of the metal layer 40 can be enlarged, and the temperature uniformity on the placement surface 61a of the electrostatic chuck 60 can be improved.

The electrostatic chuck 60 is provided on the metal layer 40. The electrostatic chuck 60 is fixed to the metal layer 40 via, for example, the adhesive layer 50. As the adhesive layer 50, for example, a silicone adhesive can be used. The thickness of the adhesive layer 50 can be, for example, approximately 2 mm. The thermal conductivity of the adhesive layer 50 is preferably 2 W/mK or more. The adhesive layer 50 may have a laminated structure in which a plurality of adhesive layers are laminated. For example, by forming the adhesive layer 50 into a two-layer structure combining an adhesive with high thermal conductivity and an adhesive with low elastic modulus, it is possible to attain an effect of reducing the stress caused by the difference in thermal expansion with the metal base plate.

The electrostatic chuck 60 is a portion that suctions and holds a wafer as an object to be suctioned. The planar shape of the electrostatic chuck 60 can be, for example, circular. The diameter of the wafer that is the object to be suctioned by the electrostatic chuck 60 can be, for example, approximately 8 inches, 12 inches, or 18 inches. The electrostatic chuck 60 includes the base 61 and an electrostatic electrode 62. The electrostatic chuck 60 is, for example, a Johnsen-Rahbek type electrostatic chuck. However, the electrostatic chuck 60 may be a Coulomb force type electrostatic chuck.

The base 61 is a dielectric material, and as the base 61, for example, ceramics such as aluminum oxide (Al₂O₃) or aluminum nitride (AlN) can be used. The thickness of the base 61 may be, for example, approximately 1 mm to 10 mm, and the dielectric constant (1 kHz) of the base 61 may be, for example, approximately 9 to 10.

The electrostatic electrode 62 is a thin film electrode and is provided in the base 61. The electrostatic electrode 62 is connected to a power source provided outside the substrate fixing device 1, and when a predetermined voltage is applied from the power source, generates an electrostatic suctioning force between the electrostatic electrode 62 and the wafer. Accordingly, the wafer can be suctioned and held on the placement surface 61a of the base 61 of the electrostatic chuck 60. The suctioning and holding force becomes stronger as the voltage applied to the electrostatic electrode 62 becomes higher. The electrostatic electrode 62 may have a monopolar shape or a bipolar shape. As the material of the electrostatic electrode 62, for example, tungsten or molybdenum can be used.

### [Method for Manufacturing Substrate Fixing Device]

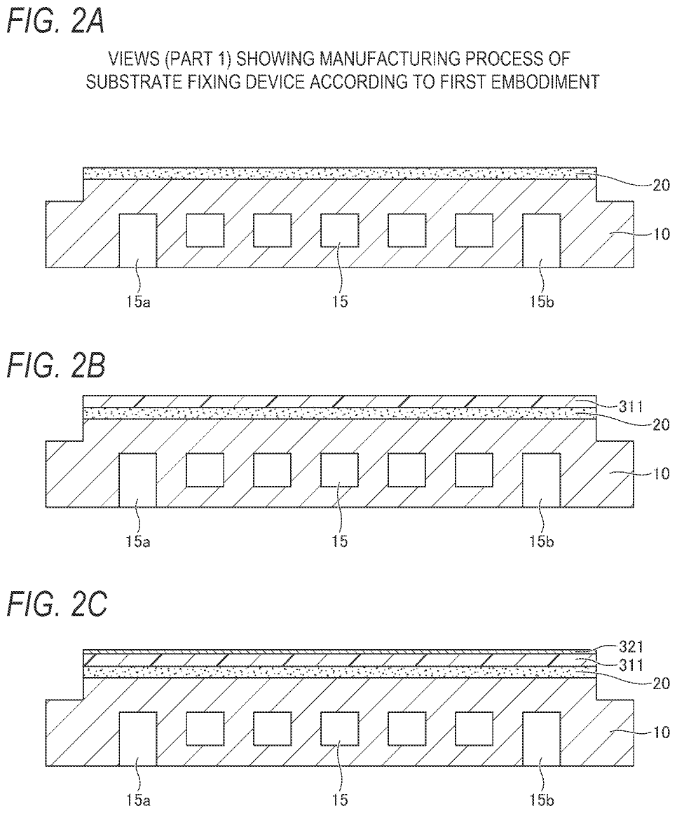

FIGS. 2A to 4B are views showing a manufacturing process of the substrate fixing device according to the first embodiment. A manufacturing process of the substrate fixing device 1 will be described with reference to FIGS. 2A to 4B.

First, in the step shown in FIG. 2A, the base plate 10 is prepared in which the water channel 15 and the like are formed in advance, and the adhesive layer 20 (uncured) is formed on the base plate 10. The material and the thickness of the adhesive layer 20 are as described above.

Next, in the step shown in FIG. 2B, an insulating resin film 311 is laminated onto the base plate 10 via the adhesive layer 20 to cure the adhesive layer 20. It is preferable to laminate the insulating resin film 311 in a vacuum because the inclusion of voids can be prevented. The insulating resin film 311 is left in a semi-cured state (a B-stage) without being cured. The insulating resin film 311 is temporarily fixed onto the adhesive layer 20 by the adhesive force of the insulating resin film 311 in the semi-cured state.

As the insulating resin film 311, for example, epoxy resin or bismaleimide triazine resin having high thermal conductivity and high heat resistance can be used. The thermal conductivity of the insulating resin film 311 is preferably 3 W/mK or more. By containing a filler such as alumina or aluminum nitride in the insulating resin film 311, the thermal conductivity of the insulating resin film 311 can be improved. The glass transition temperature of the insulating resin film 311 is preferably 250° C. or higher. From the viewpoint of improving the heat conduction performance (increasing heat conduction speed), the thickness of the insulating resin film 311 is preferably 60 μm or less, and the thickness variation of the insulating resin film 311 is preferably 10% or less.

Next, in the step shown in FIG. 2C, a metal foil 321 is provided on the insulating resin film 311. Since the metal foil 321 is a layer that eventually becomes the heating element 32, the material of the metal foil 321 is the same as the material of the heating element 32 already illustrated. The thickness of the metal foil 321 is preferably 100 μm or less in consideration of wiring formability by etching. The metal foil 321 is temporarily fixed onto the insulating resin film 311 by the adhesive force of the insulating resin film 311 in the semi-cured state.

It is preferable to roughen at least one surface (one or both of the upper and lower surfaces) of the metal foil 321 before providing the metal foil 321 on the insulating resin film 311. Of course, both the upper and lower surfaces of the metal foil 321 may be roughened. In this case, different roughening methods may be used for the upper surface and the lower surface of the metal foil 321. The roughening method is not particularly limited, and examples thereof include a method using etching, a method using a coupling agent-based surface modification technique, and a method using dot processing using a UV-YAG laser having a wavelength of 355 nm or less.

In the method using dot processing, a necessary region of the metal foil 321 can be selectively roughened. Therefore, in the method using dot processing, it is not necessary to roughen the entire region of the metal foil 321, and it is sufficient to roughen the region to be left as the heating element 32 at the bare minimum (that is, it is not necessary to roughen the region to be removed by etching).

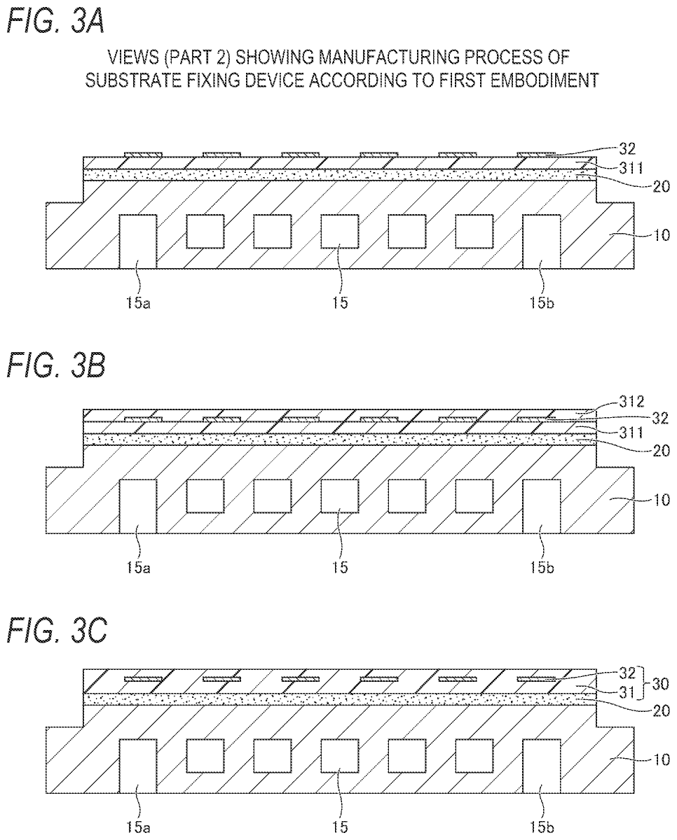

Next, in the step shown in FIG. 3A, the metal foil 321 is patterned to form the heating element 32. The heating element 32 can have, for example, a concentric circular pattern. Specifically, for example, a resist is formed on the entire surface of the metal foil 321, and the resist is exposed and developed to form a resist pattern that covers only the portion to be left as the heating element 32. Next, the portion of the metal foil 321 not covered with the resist pattern is removed by etching. For example, when the material of the metal foil 321 is copper, as the etching solution for removing the metal foil 321, a cupric chloride etching solution, a ferric chloride etching solution, or the like can be used.

Thereafter, by peeling off the resist pattern with the stripping liquid, the heating element 32 is formed at a predetermined position of the insulating resin film 311 (the photolithography method). By forming the heating element 32 using the photolithography method, it is possible to reduce the variation in the dimension of the heating element 32 in the width direction, and to improve the heat generation distribution. The cross-sectional shape of the heating element 32 formed by etching can be, for example, a substantially trapezoidal shape. In this case, the difference in wiring width between the surface in contact with an insulating resin film 312 and the opposite surface thereof can be, for example, approximately 10 μm to 50 μm. By forming the cross-sectional shape of the heating element 32 in a simple and substantially trapezoidal shape, the heat generation distribution can be improved.

Next, in the step shown in FIG. 3B, the insulating resin film 312 that covers the heating element 32 is laminated onto the insulating resin film 311. It is preferable to laminate the insulating resin film 312 in a vacuum because the inclusion of voids can be prevented. The material of the insulating resin film 312 can be the same as, for example, the insulating resin film 311. However, the thickness of the insulating resin film 312 can be appropriately determined within a range that can cover the heating element 32, and does not necessarily need to be the same thickness as the insulating resin film 311.

Next, in the step shown in FIG. 3C, while the insulating resin films 311 and 312 are pressed toward the base plate 10, the insulating resin films 311 and 312 are heated to a curing temperature or higher and are cured. Accordingly, the insulating resin films 311 and 312 are integrated to form the insulating layer 31, the heating portion 30 is formed in which the periphery of the heating element 32 is covered with the insulating layer 31, and the insulating layer 31 of the heating portion 30 and the base plate 10 are bonded via the adhesive layer 20. In consideration of the stress when the temperature returns to the room temperature, the heating temperature of the insulating resin films 311 and 312 and the adhesive layer 20 is preferably 200° C. or less.

By heating and curing the insulating resin films 311 and 312 and the adhesive layer 20 while pressing the insulating resin films 311 and 312 and the adhesive layer 20 toward the base plate 10, the unevenness of the upper surface (the surface on the side not in contact with the base plate 10) of the insulating layer 31 due to the influence of the presence or absence of the heating element 32 can be reduced and flattened. The unevenness of the upper surface of the insulating layer 31 is preferably 7 μm or less. By setting the unevenness of the upper surface of the insulating layer 31 to 7 μm or less, it is possible to prevent air bubbles from being drawn in between the insulating layer 31 and the metal layer 40 in the next step.

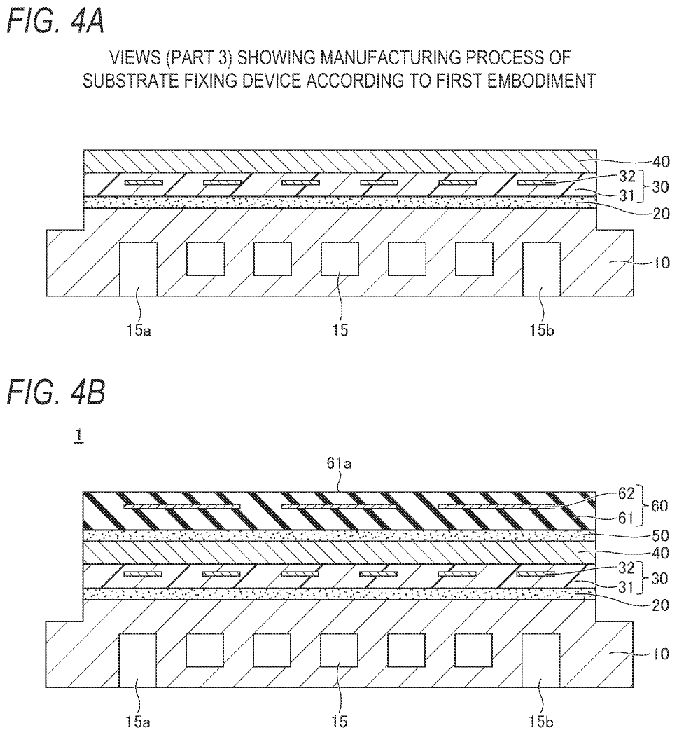

Next, in the step shown in FIG. 4A, the metal layer 40 is formed on the insulating layer 31. The material and the thickness of the metal layer 40 are as described above. The metal layer 40 can be formed by, for example, attaching a metal plate or a metal foil to the upper surface of the insulating layer 31. The metal layer 40 may be formed on the upper surface of the insulating layer 31 by a printing method, a plating method, a sputtering method, or the like. If necessary, the opening 40x can be formed in the metal layer 40.

Next, in the step shown in FIG. 4B, the adhesive layer 50 (uncured) is formed on the metal layer 40. The material and the thickness of the adhesive layer 50 are as described above. Thereafter, the electrostatic chuck 60 in which the electrostatic electrode 62 is provided in the base 61 is provided on the adhesive layer 50, and the adhesive layer 50 is cured. Accordingly, the substrate fixing device 1 is completed. The electrostatic chuck 60 can be manufactured by a well-known manufacturing method including, for example, a step of processing the via on the green sheet, a step of filling the via with the conductive paste, a step of forming the pattern to be the electrostatic electrode, a step of laminating and firing another green sheet, and a step of flattening the surface. In order to improve the adhesion with the adhesive layer 50, the lower surface of the electrostatic chuck 60 may be roughened by performing a blasting treatment or the like.

The method for manufacturing the substrate fixing device 1 shown in FIGS. 2A to 4B is an example, and the substrate fixing device 1 may be manufactured by another manufacturing method.

Next, the study result of the inventors related to the temperature uniformity will be described. The inventors conducted a simulation under three conditions for the temperature uniformity on the placement surface of the base when changing the ratio of the thickness of the metal layer to the thickness of the heating element in the structure of the substrate fixing device shown in FIG. 1. Specifically, a simulation was conducted for the temperature uniformity on the placement surface of the base when the thickness of the heating element was 50 μm and the thickness of the metal layer was 0 times (that is, no metal layer is provided), 5 times, and 10 times the thickness of the heating element. As the material of the base plate and the metal layer, aluminum was assumed.

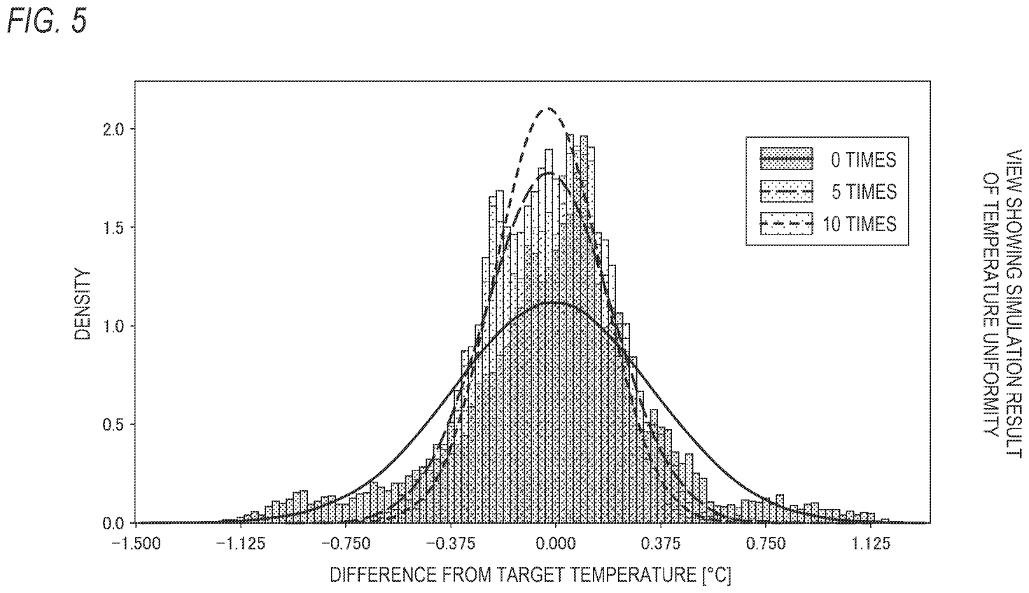

FIG. 5 is a view showing a simulation result of temperature uniformity. Table 1 summarizes the data in FIG. 5.

TABLE 1

| | Ratio of thickness of metal | |
|---|---|---|
| | layer to thickness of heating | Range of temperature |
| Conditions | element | distribution for condition 1 |
| 1 | 0 times (no metal layer) | Ref. |
| 2 | 5 times | 56% |
| 3 | 10 times | 41% |

In FIG. 5, the horizontal axis shows the difference from the target temperature when temperature measurement points are uniformly arranged on the placement surface of the base, and the vertical axis shows the density (all sum up to 100).

In FIG. 5 and Table 1, when comparing 0 times and 5 times, it can be confirmed that 5 times has a narrower range of the temperature distribution with respect to the target temperature. That is, it can be confirmed that the temperature uniformity on the placement surface of the base is improved by providing the metal layer.

In FIG. 5 and Table 1, when comparing 5 times and 10 times, it can be confirmed that 10 times has a narrower range of the temperature distribution with respect to the target temperature. That is, it can be confirmed that the temperature uniformity on the placement surface of the base is improved as the thickness of the metal layer is larger with respect to the thickness of the heating element.

From the analysis results in FIG. 5 and Table 1, it can be seen that the temperature distribution range under a condition 2 (the thickness of the metal plate is 5 times) is approximately 44% smaller than the temperature distribution range under a reference condition 1 (no metal layer). It can be seen that the temperature distribution range under a condition 3 (the thickness of the metal plate is 10 times) is approximately 59% smaller than the temperature distribution range under the reference condition 1.

Although the preferred embodiment and the like have been described in detail, the present invention is not limited to the embodiment and the like described above, and various modifications and substitutions can be made to the embodiment and the like described above without departing from the scope of the claims.

For example, as the object to be suctioned of the substrate fixing device according to the present invention, a glass substrate or the like used in the manufacturing process of a liquid crystal panel or the like may be exemplified in addition to a semiconductor wafer (a silicon wafer or the like).

What is claimed is:

1. A substrate fixing device comprising:
a base plate;
a heating portion provided on the base plate;
a metal layer provided on the heating portion; and
an electrostatic chuck provided on the metal layer,
wherein the metal layer is made of the same material as the base plate.

2. The substrate fixing device according to claim 1,
wherein the heating portion includes an insulating layer and a heating element provided in the insulating layer, and
wherein a thickness of the metal layer is 5 times or more a thickness of the heating element.

3. The substrate fixing device according to claim 2,
wherein the thickness of the metal layer is 10 times or more the thickness of the heating element.

4. The substrate fixing device according to claim 2,
wherein the thickness of the metal layer is 100 μm or more and 1000 μm or less.

5. The substrate fixing device according to claim 2,
wherein the metal layer is provided directly on an entire surface of the insulating layer on an electrostatic chuck side.

6. The substrate fixing device according to claim 5,
wherein a through hole penetrating from the base plate to the electrostatic chuck is formed, and
wherein the metal layer has an opening at a position corresponding to the through hole.

7. The substrate fixing device according to claim 6,
wherein a side surface of the metal layer is exposed to an outside.
